(19) United States
(12) Patent Application Publication
(10) Pub. No.: US 2013/0005077 A1
(43) Pub. Date: Jan. 3, 2013

(54) APPARATUS AND METHOD OF MANUFACTURING ORGANIC ELECTRONIC COMPONENT

(75) Inventors: Hsin-Fei Meng, Hsinchu City (TW); Hsiao-Wen Zan, Hsinchu County (TW); Sheng-Fu Horng, Hsinchu City (TW); Hsiu-Yuan Yang, Hsinchu County (TW); Kuo-Jui Huang, Hsinchu County (TW); Hao-Wen Chang, Taoyuan County (TW); Chun-Yu Chen, Taichung City (TW); Yu-Chiang Chao, Taoyuan County (TW); Yu-Fan Chang, Hsinchu County (TW); Bo-Jie Chang, Kaohsiung City (TW)

(73) Assignee: NATION CHIAO TUNG UNIVERSITY, HSINCHU CITY (TW)

(21) Appl. No.: 13/281,665

(22) Filed: Oct. 26, 2011

(30) Foreign Application Priority Data
Jun. 30, 2011 (TW) 100123192

(51) Int. Cl. H01L 51/40; H05K 13/00; B05C 9/14

(52) U.S. Cl. 438/99; 118/58; 29/592.1; 257/E51.002

(57) ABSTRACT

A chemical mechanical polishing method is provided. The chemical mechanical polishing method includes steps of providing a plurality of semiconductor elements to be polished, obtaining a respective dimension of the each semiconductor element to be polished, and polishing the each semiconductor element according to the respective dimension thereof.

The application claims the benefit of Taiwan Patent Application No. 100123192, filed on Jun. 30, 2011, in the Taiwan Intellectual Property Office, the disclosures of which are incorporated herein in their entirety by reference.

### FIELD OF THE INVENTION

The present invention relates to an apparatus of manufacturing an electronic component and a method thereof, and more particularly to an apparatus of manufacturing an organic electronic component and a method thereof.

### BACKGROUND OF THE INVENTION

The development of organic electronic components, such as organic light-emitting diodes (OLED), organic thin-film transistors (OTFT) and organic solar cells, has generated great interest in recent years due to the characteristics of low-temperature process, light weight and simple manufacture of the organic materials. Particularly, the development of OLED is very fast. It appears that the development of OLED has been quite mature since either of the single-color passive matrix display and the polymer full-color active matrix display has been manufactured.

Due to a low cost solution process, the polymer light-emitting diode (PLED) has the potential to be more competitive than the small molecule OLED in many applications. Currently, the most common fabrication process for PLED is spin coating. However, the usage of materials is only 5% and the manufacturing throughput by spin coating is low for large areas.

Moreover, it is difficult to make multilayer polymer structures by spin coating because the solvent of the second layer will dissolve the first layer. Therefore, currently the main process of manufacturing the organic electronic components having multilayer structures is evaporation. The cost of evaporation is high and it is also difficult to produce the components having large areas.

For overcoming the drawbacks in the prior art, an improved solution process for manufacturing the organic electronic components having multilayer structures will significantly reduce the production cost and facilitate the commercialization and mass production of the organic electronic components.

### SUMMARY OF THE INVENTION

In accordance with one aspect of the present invention, an apparatus of manufacturing an organic electronic component is provided. The apparatus includes a substrate, a first heating device, a coating device and a second heating device. The first heating device is configured to heat the substrate, the coating device is configured to coat the substrate with a material of the organic electronic component, and the second heating device is disposed in a position different from that of the first heating device.

In accordance with another aspect of the present invention, a method of manufacturing an organic electronic component is provided. The method includes the following steps: providing a substrate; providing a first heat source to heat the substrate; disposing a material of the organic electronic component on the substrate; and providing a second heat source to heat the material.

In accordance with a further aspect of the present invention, an apparatus of manufacturing an organic electronic component is provided. The apparatus includes a first heating device and a second heating device, wherein the second heating device is disposed in a position different from that of the first heating device.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a diagram showing an apparatus of manufacturing an organic electronic component according to an embodiment of the present invention.

FIG. 2 is a diagram showing an apparatus of manufacturing an organic electronic component according to a further embodiment of the present invention.

FIGS. 3(A) and 3(B) are diagrams showing performance of a component manufactured according to the present invention compared with that manufactured by a prior art.

FIGS. 4(A) and 4(B) are diagrams showing performance of a component of small molecule materials manufactured according to the present invention.

### DETAILED DESCRIPTION OF THE PREFERRED EMBODIMENT

The present invention will now be described more specifically with reference to the following embodiments. It is to be noted that the following descriptions of embodiments of this invention are presented herein for the purposes of illustration and description only; it is not intended to be exhaustive or to be limited to the precise form disclosed.

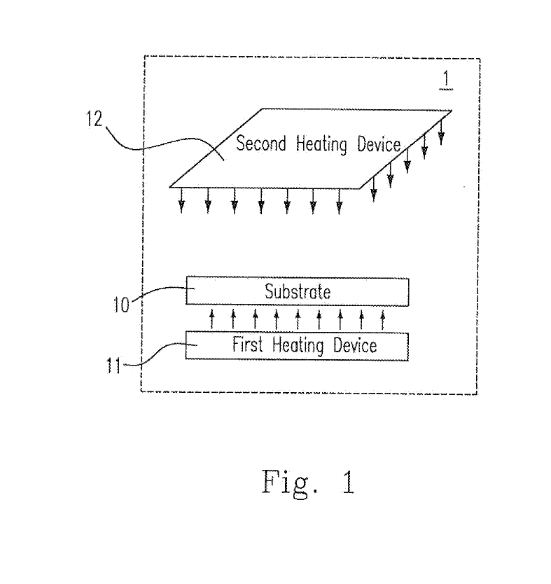

Please refer to FIG. 1, which is a diagram showing an apparatus of manufacturing an organic electronic component according to an embodiment of the present invention. The apparatus 1 of manufacturing an organic electronic component includes a first heating device 11 and a second heating device 12, wherein the second heating device 12 is disposed in a position different from that of the first heating device 11. In FIG. 1, the first heating device 11 is disposed under a substrate 10, and the second heating device 12 is disposed above the substrate 10.

It can be appreciated that the respective positions of the first heating device 11 and the second heating device 12 are not limited to those shown in FIG. 1. The second heating device 12 may be disposed in any position other than that of the first heating device 11, as long as a heat source provided thereby is enough to achieve a heating effect in the apparatus 1. Furthermore, the position of the first heating device 11 is not limited to that under the substrate 10, either, but may be disposed in any position other than that of the second heating device 12, as long as a heat source provided thereby is enough to achieve a heating effect on the substrate 10.

For example, when the first heating device 11 is disposed under the substrate 10, the second heating device 12 may be disposed in one of positions above and around the substrate 10. Alternatively, both of the first heating device 11 and the second heating device 12 are disposed in one of positions above and under the substrate 10, while in different level (height) positions or plane coordinates.

The examples of the first heating device 11 or the second heating device 12 include a hot plate, a hot wind generating device, an oven, a far-infrared heater, and so on.

In FIG. 1, the substrate 10 may include a first and a second parts (not shown in the figures), wherein the first heating device 11 heats the first part and the second heating device 12 heats the second part. For example, the first part may include the bottom surface of the substrate 10, and the second part includes all other parts of the substrate 10 except the first part. In a practical operation, since both the first heating device 11 and the second heating device 12 continuously provide heat sources in the manufacturing process of the organic electronic component, the first heating device 11 may assist in heating the second part and the second heating device 12 may heat the first and the parts, simultaneously.

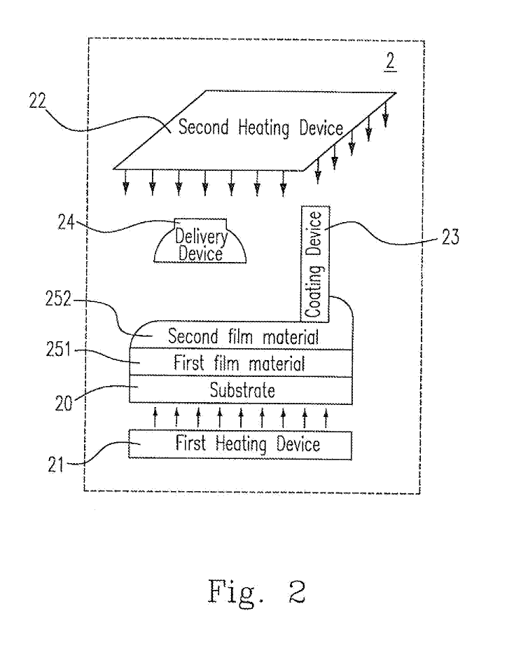

Please refer to FIG. 2, which is a diagram showing an apparatus of manufacturing an organic electronic component according to a further embodiment of the present invention. The apparatus 2 of manufacturing an organic electronic component includes a substrate 20, a first heating device 21 heating the substrate 20, a coating device 23 coating the substrate 20 with a film material (251 or 252) of the organic electronic component; and a second heating device 22 disposed in a position different from that of the first heating device 21.

Furthermore, the apparatus 2 may include a delivery device 24 delivering the film material (251 or 252) to the substrate 20. Preferably, the delivery device 24 is a precision delivery device having ability of determining quantity precisely. Preferably, the delivery device 24 has an accuracy to μL level and delivers the organic materials and the solvent thereof, included by the film material (251 or 252), to the substrate 20.

A process of manufacturing the organic electronic component by using the apparatus 2 are further described as follows.

a) The substrate 20 is heated by using the first heating device 21, wherein a heating temperature for the substrate 20 may depend on the type of the organic materials and/or other conditions of the process. For example, the temperature of the substrate 20 may be controlled in a range from 20° C. to 150° C.

b) The delivery device 24 is used to deliver the second film material 252 to the substrate 20 on which the first film material 251 being a dry film has been disposed in this embodiment.

c) The coating device 23 is used to coat the substrate 20 with the film material 252 to form an uniform wet film.

d) The second heating device 22 is disposed in one of positions above and around the wet film for accelerating an evaporation of the solvent in the wet film. A heating temperature and heating time of the second heating device 22 may depend on the type of the organic materials and/or other conditions of the process. For example, the heating temperature may be in a range from 20° C. to 200° C. and heating time may be in a range from 1 to 20 seconds.

e) When the second film material 252 has become a dry film, the coating process of the second material has beem completed. The mentioned steps can be repeated to manufacture the multilayer structures of the organic electronic component.

FIG. 2 and the mentioned steps are embodiments of the present invention describing the coating of the second film material 252 of the organic electronic component. It shall be appreciated that the apparatus and methods of manufacturing an organic electronic component according to the present invention may be directly applied in the coating of the first film material 251 on the substrate 20.

In the mentioned embodiments, the second heating device 22 is mainly configured to heat the materials (251 or 252) coated on the substrate 20. However, practically the second heating device 22 may also be configured to heat the substrate 20. Similarly, the first heating device 21 is configured to heat the substrate 20 while assist in heating the materials (251 or 252) on the substrate 20, so as to accelerate the evaporation of the solvent as abovementioned.

In the mentioned embodiments, the accuracy of the solution can be controlled by the delivery device 24 to about 0.5 μL, and thus a material usage up to almost 100% may be achieved and it is possible to prevent the excess solution of the second film material from dissolving the first film material 251. The delivery way of the delivery device 24 may be once or continuous, and a delivery frequency thereof may be adjusted according to an amassment of the solution in front of the coating device 23.

In the mentioned embodiments, the coating device 23 may include a blade coater, or other instruments capable of coating the substrate 20 with organic and oxide semiconductor materials to form an uniform thin film. The gap of blade of the coating device 23 is, for example, in a range from 10 μm to 500 μm, so that the organic and oxide semiconductor materials having a thickness of wet film of 10 μm to 500 μm could be formed. Furthermore, the amassment is preferably about 0.5-5 μL, per 1 cm (length of the blade) when the materials are delivered.

In the mentioned embodiments, the temperature of the solution to be delivered may be pre-controlled in a range of 20° C. to 150° C., for examply.

In the mentioned embodiments, the substrates 10 or 20 includes an Indium Tin Oxide (ITO) substrate.

In the mentioned embodiments, the organic electronic component includes one selected from a group consisting of an organic light-emitting device, an organic transistor, an organic solar cell and an organic photodetector. Moreover, the apparatus and methods of the present invention are mainly applied to a solution process of the organic electronic component.

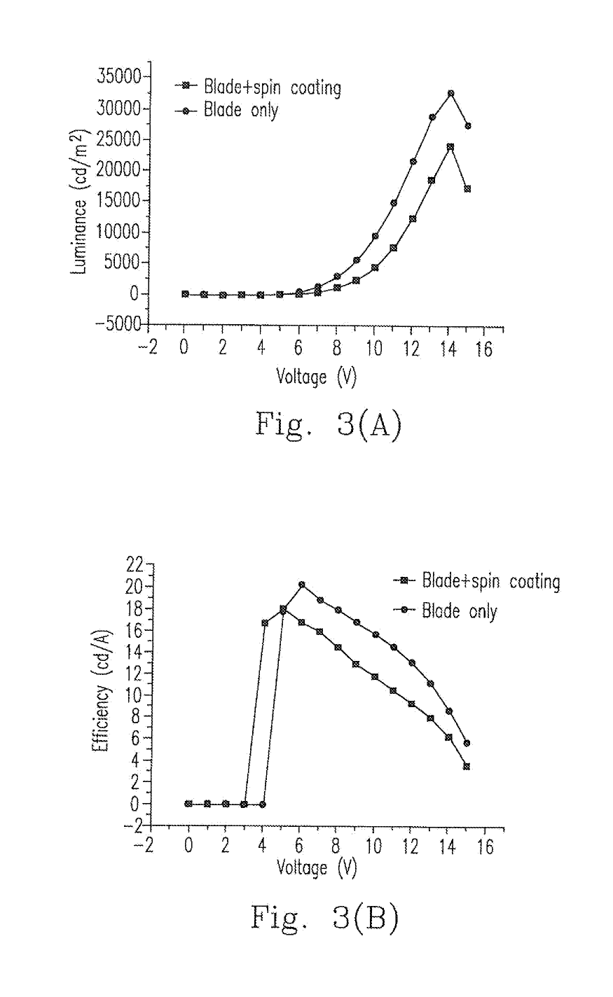

Please refer to FIGS. 3(A) and 3(B), which are diagrams showing performance of a component manufactured according to the present invention compared with that manufactured by a prior art. In FIGS. 3(A) and 3(B), the organic electronic component manufactured according to the present invention is ITO/PEDOT(AI4083)/TFB/Ir(mppy)₃: TPD:PBD:PVK/TPBi/LiF/Al and has a multi-layer structure. FIG. 3(A) shows performance of luminance and FIG. 3(B) shows performance of current efficiency of the components, wherein the square points represent the performance of the component manufactured by blade coating with spinning of prior art, and the circle points represent the performance of the component manufactured only by blade coating according to the present invention.

As known by referring to FIGS. 3(A) and 3(B), the performance of the component manufactured according to the present invention is equal to that manufactured by blade coating with spinning.

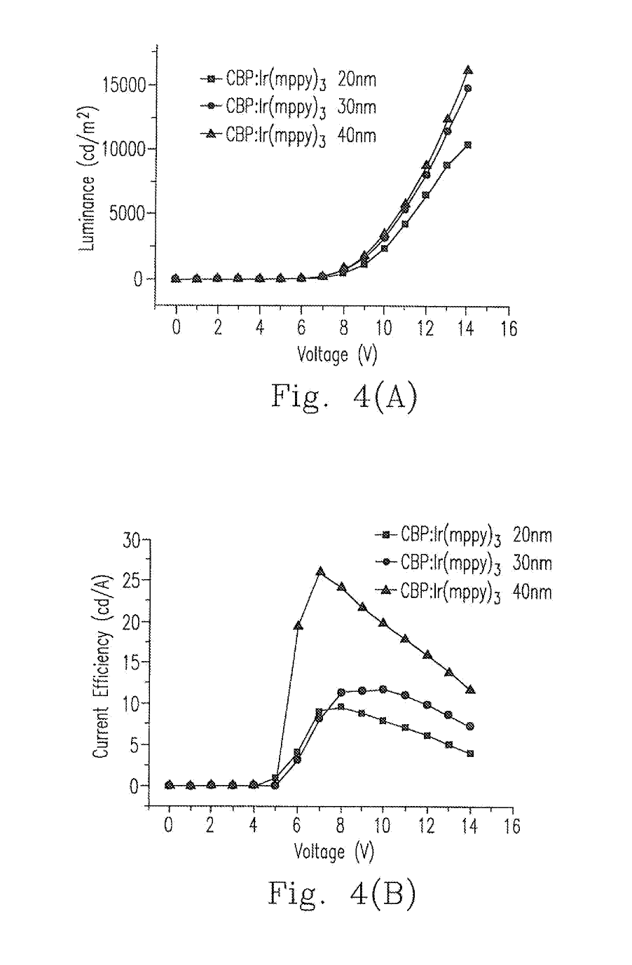

Please refer to FIGS. 4(A) and 4(B), which are diagrams showing performance of a component of small molecule materials manufactured according to the present invention. In FIGS. 4(A) and 4(B), the organic electronic component of small molecule manufactured according to the present invention is ITO/ PEDOT(AI4083)/TCTA/CBP:Ir(mppy)₃/TPBi/LiF/Al. FIG. 4(A) shows performance of luminance and FIG. 4(B) shows performance of current efficiency of the components, wherein the square, circle and triangle points respectively represent the performance of the components having different thickness of the CBP:Ir(mppy)₃ layer.

As known by referring to FIGS. 4(A) and 4(B), even small molecule materials, which have worse solubility, can form a film on the substrate by using the apparatus and methods of the present invention for manufacturing the organic electronic component, which has pretty good performance of both luminance and efficiency.

Based on above, the apparatus and methods provided in the present invention can be used to manufacture organic electronic components having large area, uniform and multi-layer structures. The production cost is significantly reduced, and the commercialization and mass production of the organic electronic components could be achieved.

### EMBODIMENTS

1. An apparatus of manufacturing an organic electronic component, comprising a substrate; a first heating device heating the substrate; a coating device coating the substrate with a material of the organic electronic component; and a second heating device disposed in a position different from that of the first heating device.

2. An apparatus of embodiment 1, wherein the organic electronic component comprises one of a single-layer structure and a multi-layer structure.

3. An apparatus of any of the preceding embodiments, wherein the organic electronic component includes one selected from a group consisting of an organic light-emitting device, an organic transistor, an organic solar cell and an organic photodetector.

4. An apparatus of any of the preceding embodiments, further comprising a delivery device delivering the material to the substrate and having an accuracy about 0.5 μL.

5. An apparatus as claimed in claim 1, wherein the coating device includes a blade coater.

6. An apparatus of any of the preceding embodiments, wherein the material includes an organic ingredient and a solvent, and the first and second heating devices accelerate an evaporation of the solvent.

7. An apparatus of any of the preceding embodiments, wherein the second heating device heats the material.

8. An apparatus of any of the preceding embodiments, wherein the first heating device also heats the material, and the second heating device also heats the substrate.

9. An apparatus of any of the preceding embodiments, wherein the first heating device is disposed under the substrate, and the second heating device is disposed in one of positions above and around the substrate.

10. A method of manufacturing an organic electronic component, comprising steps of providing a substrate; providing a first heat source to heat the substrate; disposing a material of the organic electronic component on the substrate; and providing a second heat source to heat the material.

11. A method of the embodiment 10, comprising a solution process, wherein the material includes organic materials and solvent, and the steps of providing the first heat source and providing the second heat source accelerate an evaporation of the solvent.

12. A method of any of the embodiments 10-11, further comprising at least one of steps of heating the material by using the first heat source and heating the substrate by using the second heat source.

13. A method of any of the embodiments 10-12, wherein the first and second heat sources are disposed in different positions.

14. A method of any of the embodiments 10-13, wherein the first heat source is disposed under the substrate, and the second heat source is disposed in one of positions above and around the substrate.

15. A method of any of the embodiments 10-14, wherein the first heat source has a heating temperature ranged from 20° C. to 150° C., and the second heat source has a heating temperature ranged from 20° C. to 200° C.

16. An apparatus of manufacturing an organic electronic component, comprising a first heating device and a second heating device disposed in a position different from that of the first heating device.

17. An apparatus of the embodiment 16, further comprising a substrate having a first and a second parts, wherein the first heating device heats the first part and the second heating device heats the second part.

18. An apparatus of any of the embodiments 16-17, wherein the first and second parts overlap.

19. An apparatus of any of the embodiments 16-18, wherein the first heating device is disposed under the substrate, and the second heating device is disposed in one of positions above and around the substrate.

20. An apparatus of any of the embodiments 16-19, wherein the first heating device also heats the second part, and the second heating device also heats the first part.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An apparatus of manufacturing an organic electronic component, comprising:
a substrate;
a first heating device heating the substrate;
a coating device coating the substrate with a material of the organic electronic component; and
a second heating device disposed in a position different from that of the first heating device.

2. An apparatus as claimed in claim 1, wherein the organic electronic component comprises one of a single-layer structure and a multi-layer structure.

3. An apparatus as claimed in claim 1, wherein the organic electronic component includes one selected from a group consisting of an organic light-emitting device, an organic transistor, an organic solar cell and an organic photodetector.

4. An apparatus as claimed in claim 1, further comprising a delivery device delivering the material to the substrate and having an accuracy about 0.5 μL.

5. An apparatus as claimed in claim 1, wherein the coating device includes a blade coater.

6. An apparatus as claimed in claim 1, wherein the material includes an organic ingredient and a solvent, and the first and second heating devices accelerate an evaporation of the solvent.

7. An apparatus as claimed in claim 1, wherein the second heating device heats the material.

8. An apparatus as claimed in claim 7, wherein the first heating device also heats the material, and the second heating device also heats the substrate.

9. An apparatus as claimed in claim 1, wherein the first heating device is disposed under the substrate, and the second heating device is disposed in one of positions above and around the substrate.

10. A method of manufacturing an organic electronic component, comprising steps of:
providing a substrate;
providing a first heat source to heat the substrate;
disposing a material of the organic electronic component on the substrate; and
providing a second heat source to heat the material.

11. A method as claimed in claim 10, comprising a solution process, wherein the material includes an organic ingredient and a solvent, and the steps of providing the first heat source and providing the second heat source accelerate an evaporation of the solvent.

12. A method as claimed in claim 10, further comprising at least one of steps of heating the material by using the first heat source and heating the substrate by using the second heat source.

13. A method as claimed in claim 10, wherein the first and second heat sources are disposed in different positions.

14. A method as claimed in claim 10, wherein the first heat source is disposed under the substrate, and the second heat source is disposed in one of positions above and around the substrate.

15. A method as claimed in claim 10, wherein the first heat source has a heating temperature ranged from 20° C. to 150° C., and the second heat source has a heating temperature ranged from 20° C. to 200° C.

16. An apparatus of manufacturing an organic electronic component, comprising:
a first heating device; and
a second heating device disposed in a position different from that of the first heating device.

17. An apparatus as claimed in claim 16, further comprising a substrate having a first and a second parts, wherein the first heating device heats the first part and the second heating device heats the second part.

18. An apparatus as claimed in claim 17, wherein the first and second parts overlap.

19. An apparatus as claimed in claim 17, wherein the first heating device is disposed under the substrate, and the second heating device is disposed in one of positions above and around the substrate.

20. An apparatus as claimed in claim 17, wherein the first heating device also heats the second part, and the second heating device also heats the first part.
